(19) United States
(12) Patent Application Publication
(10) Pub. No.: US 2025/0102605 A1
(43) Pub. Date: Mar. 27, 2025

(54) Rapid non-Cartesian reconstruction using an implicit representation of GROG kernels

(71) Applicant: The Board of Trustees of the Leland Stanford Junior University, Stanford, CA (US)

(72) Inventors: Kawin Setsompop, Stanford, CA (US); Daniel Raz Abraham, Palo Alto, CA (US)

(21) Appl. No.: 18/892,532

(22) Filed: Sep. 22, 2024

Related U.S. Application Data
(60) Provisional application No. 63/539,908, filed on Sep. 22, 2023.

(51) Int. Cl. G01R 33/48; G01R 33/56

(52) U.S. Cl. CPC G01R 33/4824; G01R 33/5608

(57) ABSTRACT

A method for magnetic resonance imaging includes a) performing by an MRI scanner an MRI scan to acquire non-Cartesian k-space MRI acquisition data; b) estimating by the MRI scanner Cartesian k-space data from the non-Cartesian k-space MRI acquisition data, wherein the estimating comprises estimating each Cartesian k-space coordinate in the Cartesian k-space data from multiple neighboring non-Cartesian k-space coordinates using an ensemble of GRAPPA kernels, where each of the GRAPPA kernels is obtained from a non-linear model trained on calibration data from an MRI calibration scan; and c) reconstructing by the MRI scanner an MRI image from the estimated Cartesian k-space data.

### CROSS-REFERENCE TO RELATED APPLICATIONS

This application claims priority from U.S. Provisional Patent Application 63/539,908 filed Sep. 22, 2023, which is incorporated herein by reference.

### STATEMENT OF FEDERALLY SPONSORED RESEARCH

None.

### FIELD OF THE INVENTION

The present invention relates generally to techniques for magnetic resonance imaging (MRI). More specifically, it relates to methods for MRI reconstruction from non-Cartesian data sampling.

### BACKGROUND OF THE INVENTION

In conventional MRI scanning, a vast majority of data acquisition is typically performed on a Cartesian grid in Fourier space/k-space. Cartesian sampling acquires k-space data on a Cartesian grid, with a fixed value of the phase-encoding gradient. Cartesian data allows the use of a fast Fourier transform algorithm to achieve fast and efficient image reconstruction. However, Cartesian acquisitions can often lead to longer scan times, due to the low encoding efficiency introduced by line-by-line scanning.

Data acquisition with non-Cartesian sampling (e.g., radial or spiral sampling which include off-grid data) can improve the performance of MR imaging, provide fast and more efficient data acquisition, and improve motion robustness. However, the image reconstruction process of non-Cartesian data is more involved and can be time-consuming, even through the use of efficient algorithms such as non-uniform FFT (NUFFT). Reconstruction complexity is further exacerbated when imaging in the presence of field imperfections.

### SUMMARY OF THE INVENTION

Herein is described a method for MRI including an efficient approach to transform non-Cartesian data into Cartesian data, to achieve simpler and faster reconstruction which enables non-Cartesian data sampling to be performed more widely in MRI. This provides the benefits of both the improved acquisition efficiency that Non-Cartesian trajectories offer, as well as the rapid reconstructions that Cartesian trajectories offer.

The present technique is an extension of GROG (Grappa Operator Gridding), which uses the multi-coil nature of MRI to linearly estimate a Cartesian k-space coordinate from the closest non-Cartesian k-space coordinate. The main drawbacks of the older techniques are noise amplification and reconstruction artifacts. The noise amplification and reconstruction artifacts mainly come from the estimation of linear functions (also called linear estimators) being limited to a single input sample, and the use of fractional powers of these linear functions to adapt to different gridding geometries (also referred to as orientations). As a result, GROG suffers from non-negligible errors in the estimated Cartesian data points.

We address the issues above by using a collection of neighboring non-Cartesian k-space coordinates to estimate a single Cartesian k-space coordinate. In order to do this properly, we use a unique linear estimator for each orientation. We define an orientation as the geometric configuration of the non-Cartesian coordinates relative to the single Cartesian coordinate. The linear estimators can be calculated using a least squares formulation on a small calibration region, which is usually acquired on most clinical scans. We describe two methods of using the ensemble of linear estimators. First, one can store and calculate (via least squares) the ensemble of linear estimators for each orientation. During inference time, we use various interpolation techniques to seamlessly use the correct linear estimator for a new gridding orientation. The second method is to use a compact neural network, which implicitly represents the collection of linear estimators, to help freely interpolate between linear estimators at different orientations. Instead of solving many least squares problems, we train our network on many simulated orientations over the calibration region. We found that both methods work well, however the machine learning approach is more generalizable and robust. Once the Cartesian coordinates are estimated, the remaining reconstruction is performed on the now Cartesian k-space data. This is much faster in comparison to a non-Cartesian reconstruction. We also highlight that the data estimation onto the Cartesian coordinates can happen while the data is being acquired, allowing for rapid real time reconstruction. Additionally, one can instead use this technique to directly perform a non-Cartesian GRAPPA reconstruction.

This method uses three novel techniques that allow for a significant improvement in reconstruction quality: 1. We use an ensemble of linear estimators to calculate a single Cartesian k-space data from a group of neighboring non-Cartesian k-space coordinates. 2. For the least squares method, we use high dimensional interpolation methods to calculate linear estimators at new gridding orientations. 3. For the machine learning method, a neural network is used to help freely interpolate between the ensemble of linear estimators. The neural network is trained on a distribution of orientations that represents the gridding task ahead, which allows for fast training. Alternatively, other non-linear models may be used.

In one aspect, the invention provides a method for magnetic resonance imaging, the method comprising: a) performing by an MRI scanner an MRI scan to acquire non-Cartesian k-space MRI acquisition data; b) estimating by the MRI scanner Cartesian k-space data from the non-Cartesian k-space MRI acquisition data, wherein the estimating comprises estimating each Cartesian k-space coordinate in the Cartesian k-space data from multiple neighboring non-Cartesian k-space coordinates using an ensemble of GRAPPA kernels, where each of the GRAPPA kernels is obtained from a non-linear model trained on calibration data from an MRI calibration scan; and c) reconstructing by the MRI scanner an MRI image from the estimated Cartesian k-space data.

In some implementations, the non-linear model is a neural network. The non-linear model may alternatively be a kernel regression model or a linear model with heuristically chosen non-linear features lifting. The non-linear features lifting may include sine and cosine positional encoding.

In the examples described, the number of inputs is set to 3 for purposes of illustration only. More generally, this of course can be changed to any positive integer value.

Compared to GROG, our method provides a lower noise-amplification and improved reconstruction quality.

### BRIEF DESCRIPTION OF THE DRAWINGS

FIG. 1A is a schematic diagram illustrating an original GROG technique uses a single Non-Cartesian source point to estimate the target Cartesian sample.

FIG. 1B is a schematic diagram illustrating an iGROG method that uses multiple (in this case three) Non-Cartesian source points to estimate the target Cartesian sample, according to embodiments of the present invention. iGROG interpolates along the readout to compute the input samples s₁,s₂,s₃, and queries the relevant GRAPPA kernel by inputting the orientation vectors d₁,d₂,d₃ into the MLP.

FIG. 2 is a schematic diagram illustrating an iGROG method according to an embodiment of the invention.

FIG. 3 is a graph of NRMSE vs number of variables, illustrating a compression curve for iGROG. It shows the final image NRMSE on the vertical axis vs number of model variables on the horizontal axis. This is shown relative to GROG, indicated by an X mark.

FIG. 4 is a graph of NRMSE vs number of virtual coils.

FIG. 5A is a graph of NRMSE vs. G-Factor for iGROG and GROG.

FIG. 5B is an image grid comparing iGROG (top row) and GROG (bottom row) reconstructions on the non-Cartesian k-space data for the mean image (left column), mean absolute difference image (middle column), and 1/g-factor map (right column).

FIG. 6 is an image grid where columns show NUFFT-based, iGROG, and GROG reconstructions of a 2D 34 ms readout spiral with R=3 under sampling. The first row shows the uncorrected, and the second row shows the Bo-corrected time segmented reconstruction with 40 time-segments.

FIG. 7 is an image grid where rows show the NUFFT-based, iGROG, and GROG reconstructions respectively. The columns show the different CG-SENSE 2D MRF subspace coefficients.

FIG. 8 is an image grid where CG-SENSE 3D Low-field MRF Subspace Coefficients

### DETAILED DESCRIPTION OF THE INVENTION

MRI data is acquired in Fourier space/k-space. Data acquisition is typically performed on a Cartesian grid in this space to enable the use of a fast Fourier transform algorithm to achieve fast and efficient reconstruction. However, it has been shown that for multiple applications, non-Cartesian data acquisition can improve the performance of MR imaging by providing fast and more efficient data acquisition, and improving motion robustness. Nonetheless, the image reconstruction process of non-Cartesian data is more involved and can be time-consuming, even through the use of efficient algorithms such as non-uniform FFT (NUFFT). This work provides an efficient approach (iGROG) to transform the non-Cartesian data into Cartesian data, to achieve simpler and faster reconstruction which should help enable non-Cartesian data sampling to be performed more widely in MRI.

Purpose: Using non-Cartesian acquisition schemes allows for faster scanning, motion robustness, and more efficient use of the gradient coils. However, these non-Cartesian acquisitions will often result in a complex and costly reconstruction scheme. iGROG is proposed to assist in reducing the reconstruction complexity.

Theory and Methods: Inspired by GROG, iGROG uses the multi-coil nature of MRI to interpolate missing k-space grid points from non-Cartesian points. In order to address the limitations of GROG, which includes noise amplification and interpolation inaccuracies, iGROG uses multiple source points instead of a single one to estimate a given Cartesian coordinate. iGROG estimates a large collection of GRAPPA kernels represent all possible gridding orientations, which naively requires a vast amount of memory and computation. To address these limitations, iGROG utilizes an implicit Multi Layer Perceptron (MLP) to compactly represent the vast amount of GRAPPA kernels required to represent all possible gridding orientations.

Results: We first use a simple phantom simulation to show that using the iGROG framework to estimate Cartesian data from non-Cartesian data outperforms GROG, improving average MSEs and reducing gFactor. We then demonstrate the use of iGROG's accurate single step gridding to run Cartesian SENSE reconstructions on estimated Cartesian data to achieve 5-10× reconstruction time and memory improvements over gold standard NUFFT and Toeplitz approaches. This is shown in a number of in vivo non-Cartesian acquisition cases.

Conclusion: iGROG is an effective framework for estimating Cartesian data from non-Cartesian data. This enables clinically relevant reconstruction times for non-Cartesian sequences, while significantly reducing the memory and processing requirements.

### INTRODUCTION

Currently, a vast majority of clinical MR scans acquire data on a Cartesian grid. Cartesian acquisitions are advantageous due to their acquisition and reconstruction simplicity. Since Cartesian acquisitions acquire samples on a Cartesian grid, image reconstruction can be performed in an efficient way using Fast Fourier Transforms (FFTs). However, Cartesian acquisitions can often lead to longer scan times, due to the low effective duty cycle (defined as the ratio of data acquisition time to sequence time). EPI and multi-shot EPI techniques are solutions which improve the duty cycle of Cartesian-like trajectories, while retaining the efficient reconstruction benefits. Nonetheless, EPI trajectories still only utilize a single effective gradient coil for image encoding, limiting the overall duty cycle.

Non-Cartesian trajectories are able to remedy many of the short comings of Cartesian trajectories. Spiral trajectories (cite PIPE, Stranger) enable 2D and 3D rapid imaging applications, allow for much shorter TEs in diffusion imaging, and are the standard choice for MRF acquisitions. Radial trajectories exhibit desirable undersampling artifacts and are extremely robust to motion. They have been used for body imaging, functional MRI, and quantitative imaging. However, these trajectories have not become a standard choice in clinical settings, due to a multitude of reasons. All non-Cartesian acquisitions will require a non-Cartesian image reconstruction, which usually results in much longer reconstruction times. Additionally, some non-Cartesian acquisitions, such as spirals, are known to be extremely sensitive to off-resonance effects, requiring off-resonance correction techniques which further burden the reconstruction time. These types of trajectories can also cause increased eddy currents, which requires more costly correction techniques. The root cause of costly reconstructions are mainly attributed to the fact that FFTs cannot be used directly since the data does not lie on a Cartesian grid. Long reconstruction times can be an issue in clinical settings, since clinical scans often rely on being able to observe the reconstructed volumes shortly after data acquisition is complete to determine the need for a rescan. Thus, it is important to have both the improved acquisition efficiency that Non-Cartesian trajectories offer, as well as the rapid reconstructions that Cartesian trajectories offer.

Non-Uniform Fast Fourier Transforms (NUFFTs) provide a significant computational improvement in comparison to the DFT approach for computing Non-Cartesian k-space samples. The NUFFT computes Non-Cartesian k-space samples by first applying an oversampled spatial FFT, followed by an interpolation with a Kaiser Bessel kernel over the entire k-space trajectory. While NUFFTs have significantly improved MRI reconstruction, they are still considered a substantial bottleneck in modern Non-Cartesian reconstruction pipelines. In most model based Non-Cartesian reconstruction frameworks, the NUFFT and its adjoint operator must be applied iteratively. To remedy the costly iterative NUFFT applications, many have used a Toeplitz (CITE) formulation to speed up the successive applications of the NUFFT and its adjoint operation. The Toeplitz formulation removes the need for a Kaiser Bessel interpolation, and instead requires the use of a 2× oversampled FFT and storing the large Toeplitz PSF. While the Toeplitz formulation was a significant improvement, the computation time of the 2× oversampled FFTs and Toeplitz PSF memory requirements can become problematic for high dimensional and high resolution MR volumes.

An alternative Non-Cartesian reconstruction approach is to instead estimate Cartesian samples from Non-Cartesian samples using GRAPPA kernels, which is called GRAPPA Operator Gridding (GROG) (CITE). Importantly, GROG estimates the Cartesian samples once before reconstruction, and the remaining reconstruction can be deployed on a Cartesian grid, which will be significantly faster than NUFFT based reconstructions. Applying GRAPPA to non-Cartesian trajectories requires the training, storage, and application of a vast amount GRAPPA kernels, which can become a computational burden. To remedy this problem, GROG trains only a few GRAPPA kernels (one for each coordinate axis), and the applies them sequentially on a Non-Cartesian sample to estimate a Cartesian sample. Following training, gridding is performed on novel gridding geometries by using fractional powers of the trained coordinate GRAPPA kernels. GROG is fast and in certain cases can provide reconstruction results that are similar to the gold standard iterative NUFFT approaches. Unfortunately, GROG suffers from non-negligible errors in the estimated cartesian data points. These errors arise from the restricted use of single input (source) single output (target) GRAPPA kernels, which are not expressive enough to capture the full redundancy along the coil dimension.

In order to improve GROG's shortcomings, we propose to instead estimate a unique GRAPPA kernel for each gridding geometry, and input multiple Non-Cartesian source samples to estimate the single target Cartesian sample. Using multiple source points helps reduce the estimation errors, and makes better of use of the coil redundancy. The main challenge to this approach is that there are a large number of unique gridding orientations, and each gridding orientation needs a unique GRAPPA kernel, which is extremely computationally demanding. Training coordinate kernels as in GROG will not work here, since multiple source points are being used. To remedy this problem, the inherent correlation between unique GRAPPA kernels is exploited to train a lower dimensional representation of the space of all GRAPPA kernels needed for gridding. A Multi-Layer Perceptron (MLP) is used to implicitly represent this low dimensional space of GRAPPA kernels, hence the name iGROG. Using implicit MLPs have been used in many computer vision tasks, and have been shown to be an effective way to represent large amounts of data in a compact and expressive way (CITE NERFs). Furthermore, implicit MLPs offer a memory efficient and fast method of querying the required GRAPPA kernels, and have significantly lower training times in comparison to training the collection of GRAPPA kernels independently.

Similar to GROG, iGROG uses multi-coil information to efficiently grid Non-Cartesian samples to their closest neighboring Cartesian samples. Furthermore, since iGROG also uses neighboring points along the readout direction only, the gridding process can be executed while the data is being acquired from the scanner. Both techniques can be viewed as fully self-supervised, and need to be re-trained on calibration data for every scan. The two key differences between iGROG and GROG are the training processes and number of points used to estimate every Cartesian sample. GROG trains a unique GRAPPA kernel for each coordinate axis, while iGROG instead trains the implicit representation of GRAPPA kernels in a stochastic manner. GROG uses a single source point to estimate a single Cartesian sample, while iGROG uses multiple source points for every single Cartesian sample.

In short, iGROG can be seen as a simple extension of GROG which better captures the available multi-coil redundancy to more accurately estimate Cartesian data from non-Cartesian data. In most cases, iGROG produces reconstructions that are competitive with NUFFT based reconstructions, while significantly reducing computational complexity. Hence, iGROG has the potential to enable the clinical usage of many non-Cartesian acquisitions, which are often not used to do the burdensome computational complexity.

### Theory

iGROG is inspired by GROG, thus we first provide a simplified technical description of how GROG works to better understand the motivation and details of iGROG.

### GROG

Much of the prior parallel imaging works, such as GRAPPA, have justified the use of linear functions, referred to as GRAPPA kernels, to estimate k-space data. GRAPPA kernels estimate a single k-space point at each coil, typically referred to as the target point, from other neighboring k-space points from all coils, which are referred to as source points. A GRAPPA kernel is a function of the sensitivity maps, and of the source point coordinates relative to the target point coordinate (which we call a gridding orientation).

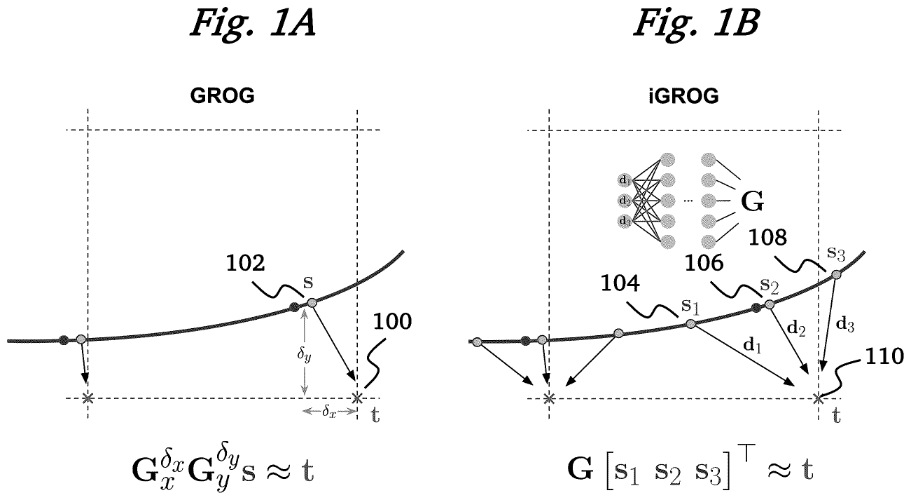

GROG proposes to use a unique GRAPPA kernel for each coordinate axis, and then applies these kernels sequentially to estimate Cartesian samples from Non-Cartesian samples. In the GROG framework, GRAPPA kernels are trained to estimate target points which are Δk=1 distance away from the source point along a single coordinate axis. All other distances can be modeled as fractional powers of the coordinate GRAPPA kernel. Let us assume some multi-channel target sample point t 100 and a multi-channel source sample point s 102 located at some position (δₓ,δ_{y},δ_{z}) relative to t, as illustrated in FIG. 1A. GROG estimates t from s using the following formulation:

$${G}^{{δ}_{x}} {G}^{{δ}_{y}} {G}^{{δ}_{z}} s = t \qquad ( 1 )$$

where δₓ,δ_{y},δ_{z} are the desired distances along each coordinate axis, Gₓ, G_{y}, G_{z} are the trained GRAPPA kernels that estimate a point Δk=1 away on each coordinate axis.

After applying GROG to the raw non-Cartesian MRI data b(t), a new set of Cartesian samples b_{grid}(t) and Cartesian k-space trajectory k_{grid}(t)∈Z^{d} is formed. Since the new data is on a Cartesian grid, the Kaiser Bessel interpolation step is no longer necessary.

While GROG provides a substantial improvement in reconstruction times, it has two main drawbacks. First, using just a single source point limits the GRAPPA kernels ability to estimate the target point, leading to artifacts and noise amplification. Furthermore, the GROG framework does not have functionality for correcting non-Fourier phase due to field imperfections. With these drawbacks in mind, we present a more general and flexible formulation of GROG.

iGROG

Our method, iGROG, differs from GROG by instead using many non-Cartesian source points (s₁ . . . s_{D}) to estimate the single target (Cartesian) point t. The relationship between the source and target points is now

$${G [ {s}_{1} … {s}_{D} ]}^{⊤} = t \qquad ( 2 )$$

where G is the GRAPPA kernel which estimates a single target point from D source points. FIG. 1B illustrates an example where three non-Cartesian source points s₁ . . . s₃ 104, 106, 108 are used to estimate the single Cartesian target point t 110. Note that the source points are chosen to be along the readout direction, as illustrated in FIG. 1B. This is done for simplicity and generality, although it is not strictly necessary.

The main challenge of this approach is that a unique GRAPPA kernel G is needed for each sample, since (in the worst case) each sample can possess a unique gridding orientation and image phase due to field imperfections. Naively estimating all of these kernels, even when using the fast GRAPPA estimation technique, is extremely computationally demanding. Training coordinate kernels as in GROG will not work here, since multiple source points are being used. To remedy this problem, the inherent correlation between unique GRAPPA kernels is exploited to train a lower dimensional representation of the space of all GRAPPA kernels needed for gridding. A Multi-Layer Perceptron (MLP) is used to implicitly represent this low dimensional space of GRAPPA kernels. These MLPs offer a memory efficient and fast method of querying the required GRAPPA kernels, and have significantly lower training times in comparison to training the collection of GRAPPA kernels independently.

We define an orientation by the positions d₁ of the source points s₁ relative to the position of target point t. We exploit the relationship between GRAPPA kernels at different orientations using an implicit MLP representation:

$$G = {f}_{θ} ( {d}_{1} , … , {d}_{{N}_{s}} ) \qquad ( 3 )$$

where f_{θ} is an MLP with parameters θ. This MLP is a compressed representation of the collection of GRAPPA kernels needed to perform gridding. Training this compressed representation allows for a significant reduction in training time and memory in comparison to naively training each unique GRAPPA kernel. We formulate the training procedure as a stochastic minimization problem:

$$θ ⋆ = arg {min}_{θ} {\sum }_{j} L ( {{G}^{( j )} [ {{s}_{1}}^{( j )} ⋯ {{s}_{D}}^{( j )} ]}^{⊤} , {t}^{( j )} ) + λ \vert \vert {G}^{( j )} {\vert \vert}^{2} \qquad ( 4 )$$

$$where$$

$${G}^{( j )} = {f}_{θ} ( {{d}_{1}}^{( j )} , … , {{d}_{D}}^{( j )} )$$

where L is the loss function and λ is a Tikhonov regularization hyper-parameter controlling the tradeoff between noise amplification and bias in the trained GRAPPA kernels.

The MLP f_{θ} is trained on the calibration data, and is then applied on the non-Cartesian data to estimate the closest Cartesian data points. Since the calibration data points are usually acquired before each scan, the training of f_{θ} can be seen as a completely self-supervised process.

GROG, iGROG, and inverse NUFFT algorithms all operate as some gridding function g(b) which takes as input non-Cartesian multi-channel k-space data b, and outputs estimated multi-channel Cartesian data points b_{grid}=g(b). The benefit of applying g once before running an iterative reconstruction is that the system's Non-Cartesian forward model A relating the image x to the acquired data b transforms into a Cartesian model A_{grid} relating x to b_{grid}. If the estimator g is sufficiently accurate at estimating Cartesian grid points from Non-Cartesian points, then

$${A}_{g r i d} x = {b}_{g r i d} ⇒ A x \approx b .$$

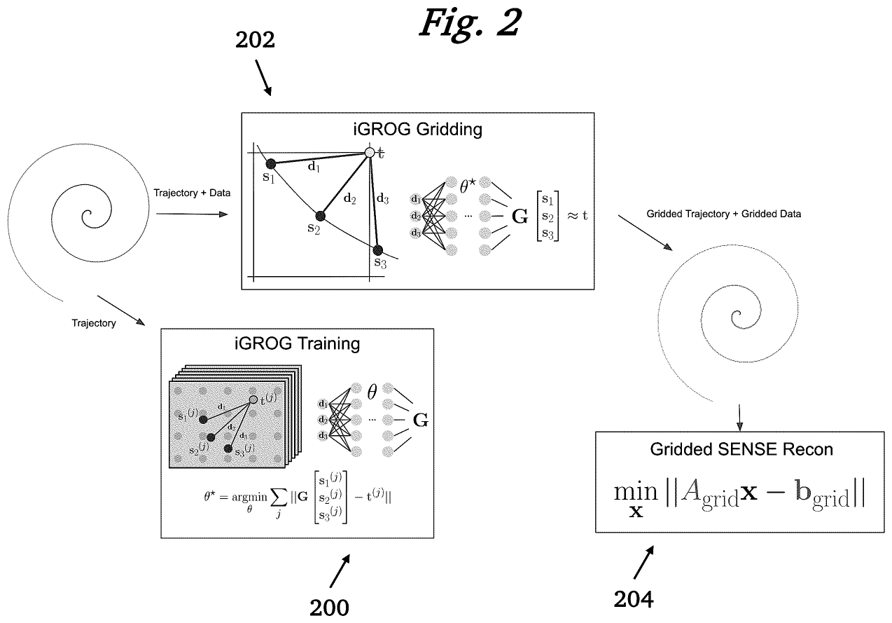

The quality of the estimator g determines the approximation error in Ax≈b. From this point forward, we will assume that g is of sufficient quality, meaning that solving the linear inverse problem for x using A_{grid}, b_{grid} is equivalent to solving the linear inverse problem using A, b. Thus, we can perform gridded reconstructions, which are much more efficient, to solve for the same underlying unknown x, also shown in FIG. 2, step 204.

We will assume that the gridding function g can be applied faster than the rate at which data is being acquired from the MR scanner, and hence can be omitted from the computational complexity analysis. Let us further assume that the data has K k-space points and C coil channels, and that the carnality of the data remains constant after gridding. x is some volume with d spatial dimensions and N grid points along each spatial dimension. The Non-Cartesian MRI linear operator A and the gridded linear operator A_{grid} can be written as

A=FS

A_{grid}=MFS
where S is a point-wise multiplication with coil sensitivity maps, F is an NUFFT operator, F is a Cartesian spatial FFT operator, and M represents a sampling mask which selects acquired grid points. The application of S is identical in both cases, and hence we will neglect the dependence on the number of coils C when analyzing the computational complexity.

Applying F is equivalent to applying an α over-sampled FFT F_{α×} followed by a Kaiser-Bessel convolutional operator P_{W} with kernel width W. The computational cost of both of these operators is O(α^{d}N^{d} log(αN)+c₁W^{d}K), where c₁ is some constant depending on the NUFFT implementation. Applying MF is equivalent to a non-oversampled FFT operation, followed by selecting K grid points, leading to a complexity of O(N^{d} log(N)+c₂K), where c₂ is a constant depending on the masking implementation.

For both the standard and gridded linear operators, one could use a Toeplitz formulation to speed up the computation of the gram operators A^{H}A,A^{H}_{grid}A_{grid}. The Toeplitz formulations for each are

F^{H}F=F^{H}_{2×}TF_{2×}

(MF)^{H}(MF)=FM^{H}MF
where both T and M^{H}M are point-wise multiplications in frequency domain. Thus, the computational complexity for the standard Non-Cartesian gram operator is O(2^{d}N^{d} log(2N)). The computational complexity for the gridded Cartesian gram operator is O(N^{d} log(N)).

### Methods

As shown in FIG. 2, the implementation methodology for iGROG involves first (step 200) training the GRAPPA Kernel MLP f_{θ}, and then using this MLP for gridding. A gridded SENSE reconstruction (step 204) is then run on the now Cartesian data to get the final image. More specifically, in step 200 the non-Cartesian trajectory is used to train the iGROG MLP on a fully sampled calibration region. In step 202 the trained MLP is then used on the raw k-space data to estimate Cartesian samples from non-Cartesian samples. In step 204 the gridded trajectory and gridded data b_{grid} are used in a gridded SENSE reconstruction. The new gridded trajectory is used to update the system's forward model to A_{grid}, which only differs by the new trajectory.

### GRAPPA Kernel Training

In order to train the MLP f_{θ}(d₁, . . . , d_{D},Δt), we must provide a sufficient number of labeled training examples. We can generate these training examples from the calibration data. The MLP is trained according to the following procedure:
1. Store all possible orientation vectors needed for gridding, or estimate a distribution of orientation vectors closely resembling all possible orientation vectors needed for gridding.
2. Randomly choose a batch of B target coordinates within the calibration bounds and use Kaiser Bessel interpolation to compute B target values {t^{(j)}|j∈[B]}.
3. Randomly choose a batch of B orientation vectors {(d₁^{(j)}, . . . , d_{D}^{(j)})|j∈[B]} from 1.
4. Use the orientation vectors and target coordinates to compute a set of B·D source coordinates and using Kaiser Bessel interpolation compute B source values {(s₁^{(j)}, . . . , s_{D}^{(j)}|j∈[B]}.
5. Update MLP parameters θ by taking a gradient step in the direction of minimizing the training loss Σ_{j=1,B} L(f_{θ}(d₁^{(j)}, . . . ,d_{D}^{(j)}) [s₁^{(j)}, . . . ,s_{D}^{(j)}]^{T},t^{(j)})+λ∥f_{θ}(d₁^{(j)}, . . . ,d_{D}^{(j)})∥².
6. Go back to 2. until convergence.

The MLP f_{θ} contains an input layer of size d·D, a few hidden layers of size 256, and an output layer of size D·N_{c}·N_{c} where d is the spatial dimension, D is the number of source points, and N_{c} is the number of coils.

### Gridding

Given a fully trained GRAPPA kernel MLP f_{θ}*, we can estimate Cartesian data samples from non-Cartesian samples as the data is being acquired from the scanner. This can be done in real time, since the source points are chosen to be along the readout direction, and hence data from each phase encode can be gridded independently. As shown in FIGS. 1A, 1B, we used a 1D interpolation to compute the samples s₁,s₂,s₃. These interpolated source points are chosen along an arc with some constant arc-length, where the center sample having minimal distance to the Cartesian coordinate t. Using data points along the readout direction only was done for simplicity of implementation. Once can also use other techniques (e.g., fessler non-cart grappa) to use source points from multiple phase encodes to estimate a single Cartesian sample.

It is important to note that there can be collisions whenever multiple sets of non-Cartesian coordinates map to a particular Cartesian coordinate more than once. These collisions are handled by simple averaging. This can be improved by taking a weighted average depending on the gridding distances (which should be proportional to the estimation errors).

### Rate Distortion Perspective

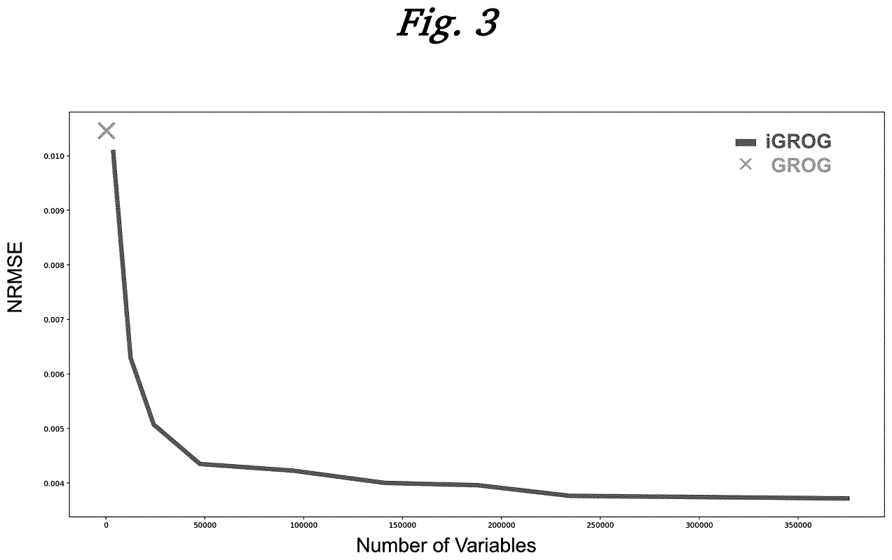

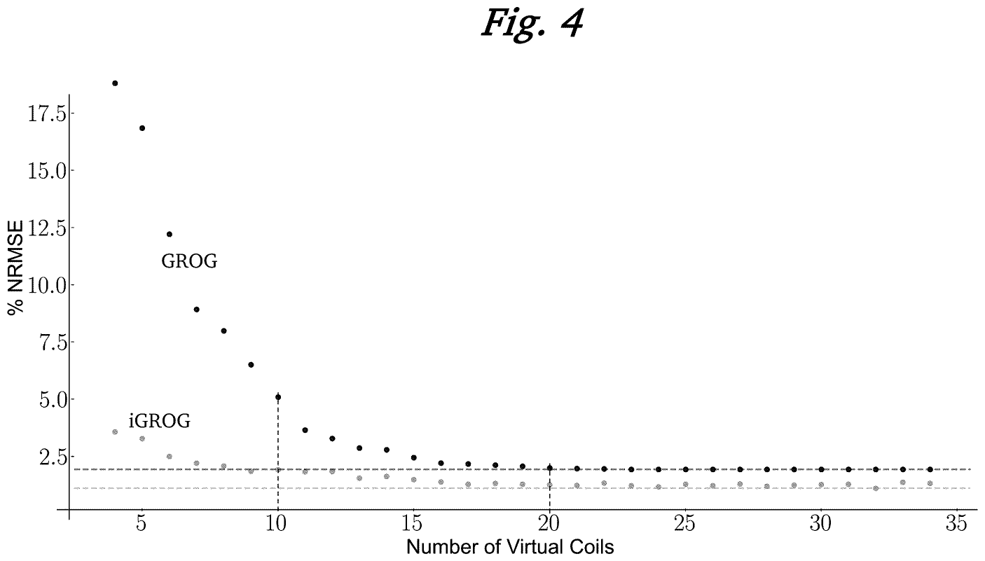

iGROG and GROG can both be seen as compression techniques. Given a large collection of orientation vectors, the goal of both iGROG and GROG is to find a compressed representation of the vast collection of GRAPPA kernels needed for each orientation vector, while maintaining high quality gridded reconstructions. Further, the compression scheme should be chosen in a way that allows for compressed training, or the ability to train on the compressed representation of GRAPPA kernels. Similar to standard lossy compression analysis techniques, iGROG and GROG will fall on some rate distortion curve, where the rate is the number of variables that need to be trained, and the distortion is the error between the estimated and ground truth reconstructions. From the curve shown in FIG. 3, iGROG is shown to approach GROG when the number of model variables is limited. As the number of variables increases, the model's expressiveness also increases, and thus the estimation ability improves.

### Efficient Linear Operator Construction

Gridded reconstructions will use the forward model A_{grid}, and NUFFT-based reconstructions will use the forward model A. Both A and A_{grid} are implemented using PyTorch. A_{grid} is implemented using simple

FFT and masking operations. A's NUFFTs are implemented using Mathew Muckley's torchkbnufft package with default parameters.

Both A^{H}_{grid}A_{grid} and A^{H}A use Toeplitz formulations to speed up the reconstructions. The Toeplitz formulation has been extended to apply to subspace and time segmented reconstructions. Coil, subspace, and time-segment batching have been implemented in order to allow the Topelitz gram operator to fit into GPU memory.

### Reconstruction

For all non-regularized reconstructions, the Conjugate Gradient algorithm is used to solve for the image.

Regularized reconstructions use FISTA with L₁ Wavelet regularization. The regularization strength is empirically chosen by running multiple regularized reconstructions with different regularization strength, and choosing the best one. Before running the iterative reconstructions, A and A_{grid} are normalized by 1/√λₘₐₓ, where λₘₐₓ is the maximum eigenvalue of A^{H}A and A^{H}_{grid}A_{grid} respectively. All reconstructions, including gridded reconstructions, use the pipe-menon method to estimate the density compensation factor (DCF). It is important to note that the DCF for the gridded trajectory differs slightly from the DCF for the non-gridded trajectory. Estimated DCFs are normalized by the maximum DCF value.

The Toeplitz kernels for gridded operators are two times smaller than the standard Toeplitz kernels in each spatial dimension. Thus, gridded reconstructions can use a larger coil batch compared to regular reconstructions. This is an important practical detail since we are almost always limited by GPU memory. Therefore, the speedup factor in gridded reconstructions comes from both the larger batch sizes and smaller FFT sizes (due to smaller Toeplitz kernels).

iGROG and GROG Parameters

Unless stated otherwise, iGROG gridding uses a fixed MLP architecture and training scheme for all reconstructions. The MLP architecture has an input layer for the orientations, three hidden layers with 256 nodes, a fourth hidden layer with 1024 nodes, and the output layer with the same dimensions as the GRAPPA kernel. The ADAM (CITE) optimizer is used with a learning rate of 10⁻³ to train the MLP under the L₁ loss function L(·)=∥·∥₁. The model is trained over 30 epochs with a batch size of 1024 and 100 randomly generated batches per epoch.

Coordinate GROG kernels have been trained using a set of different tikonov regularization values. For each experiment, the best reconstruction is chosen from the set of different regularization values.

### Readout Interpolation

Readout samples are interpolated in order to minimize the gridding distances (and hence gridding errors) for both iGROG and GROG, as shown in FIGS. 1A, 1B. These interpolated samples are non-uniform relative to the raw temporal k-space signal. Sinc interpolation is the preferred choice for synthesizing these non-uniform interpolated samples. However, efficient algorithms are hard to come by due to the requirement of non-uniform interpolated samples, which disqualifies filter-bank or Fourier techniques. In order to have efficient readout interpolation, we first up-sample the raw data to a fixed 4X oversampling rate, and finally use a linear interpolation to estimate the non-uniform samples. This has been validated against a standard sinc interpolation, and achieves similar results.

### Calibration

Since both iGROG and GROG need a calibration region to train their respective GRAPPA kernel representations, a calibration region is either explicitly provided to the algorithm by a separate scan, or is synthesized from the center of k-space in the case of MRF subspace experiments. Calibration synthesis can be performed with MRF acquisitions due to the oversampling of the combined contrast center k-space. In order to ensure that edge effects do not corrupt the GRAPPA kernel estimation process, we omit a region of 2Δk points around the boundary of the calibration region.

### G-Factor Experiments

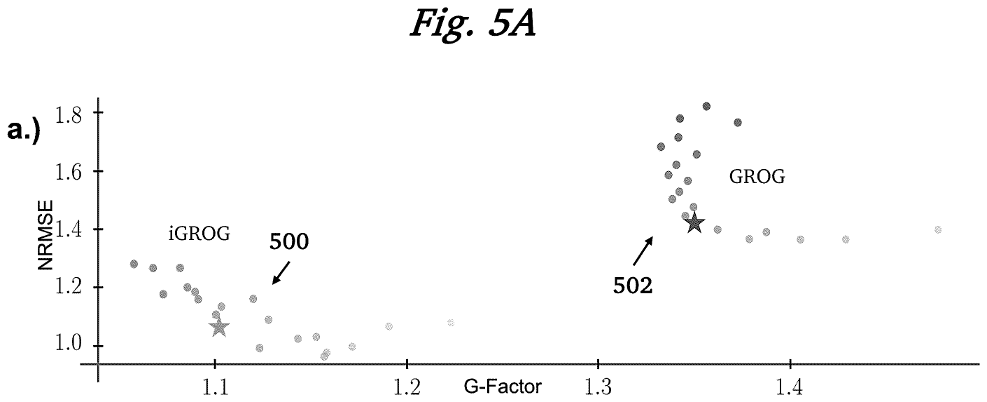

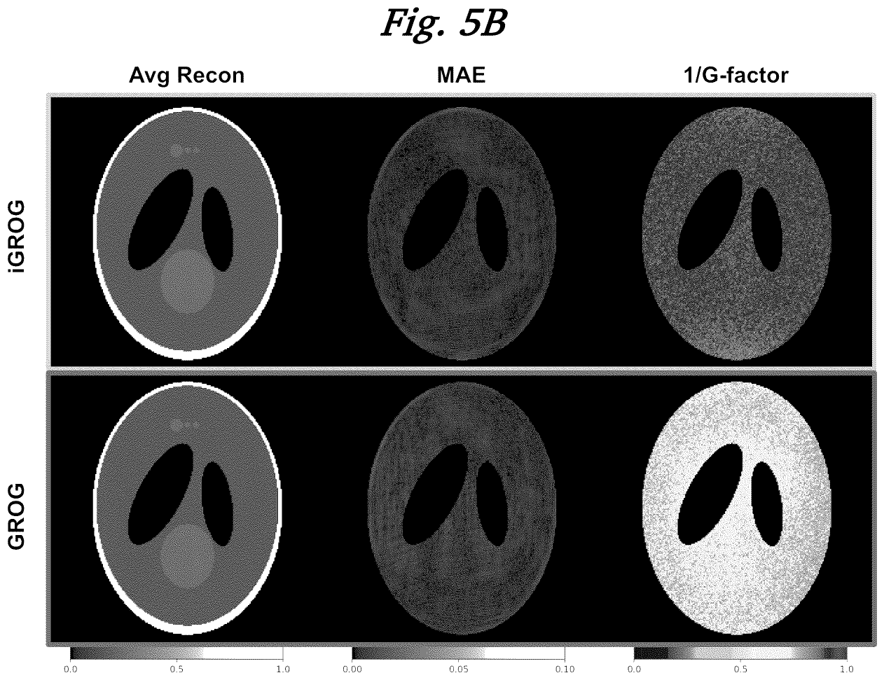

To evaluate the bias and variance of iGROG and GROG as Cartesian estimators, the pseudo-replica g-factor method is used (CITE). The Shepp-Logan phantom with image matrix size (256, 256) is used as ground truth. Multi-channel k-space data from 12 birdcage coils were simulated using the Sigpy (CITE) library. A 16-shot variably density spiral trajectory was used with an undersampling factor of R=2, giving 8 total shots. The number of G-factor noise iterations was set to 500. The columns of the image grid in FIG. 5B represent the mean image, mean absolute difference image, and 1/g-factor map respectively. The rows are the iGROG and GROG reconstructions respectively on the non-Cartesian k-space data. FIG. 5A shows a graph of NRMSE vs. G-Factor for iGROG 500 and GROG 502.

### 2D Long Readout Spiral

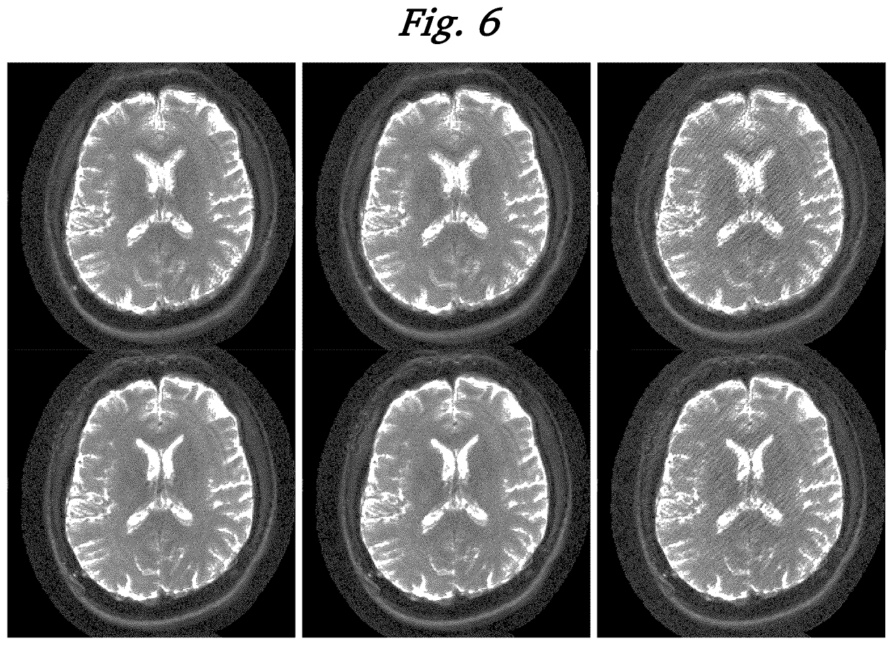

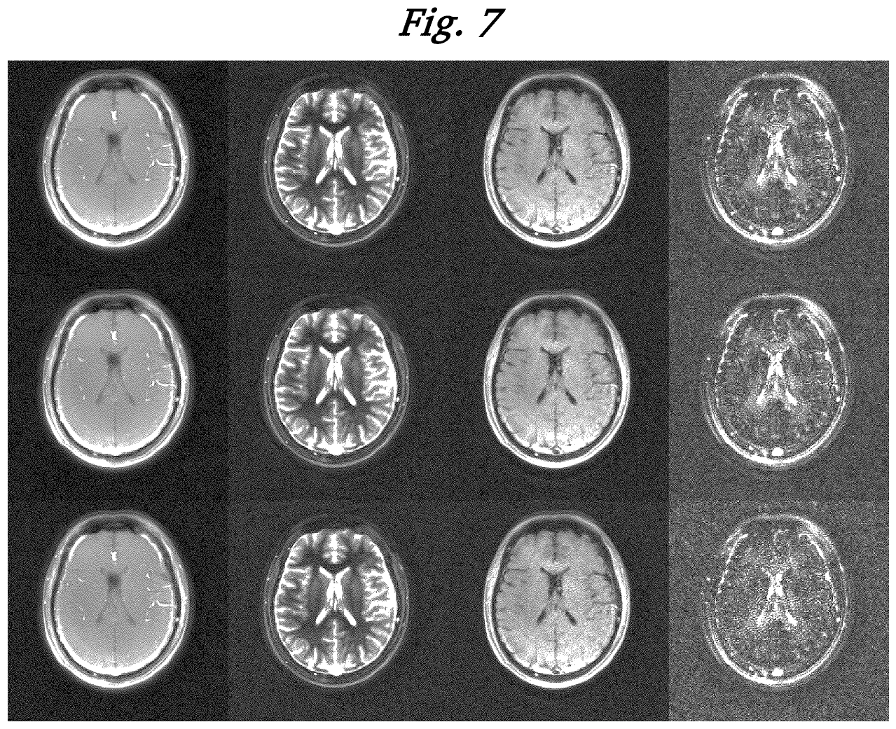

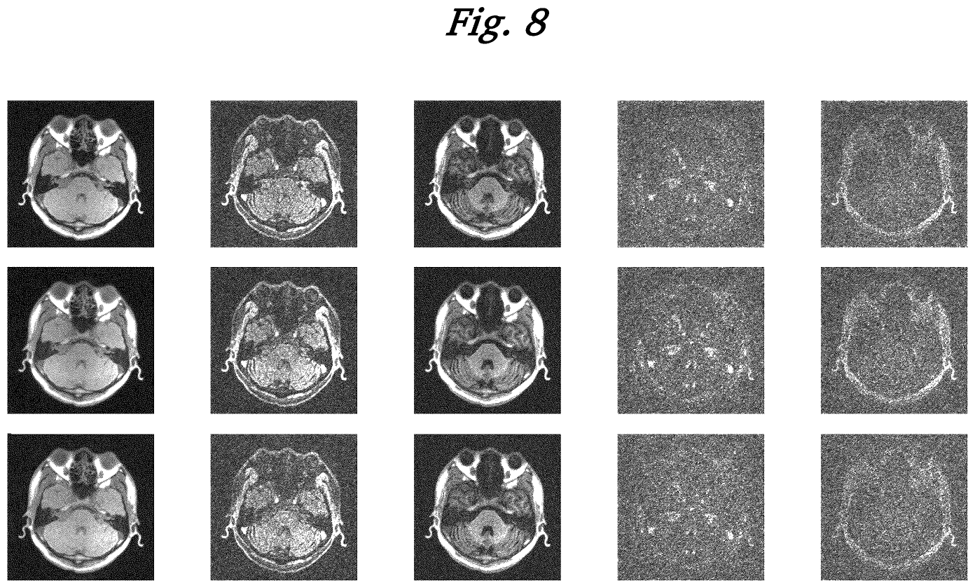

Long readout spiral trajectories require off resonance correction, which can be quite costly to reconstruct. We evaluate a 2D example acquisition with a 34 ms R=3 under sampled 3 shot variable density spiral. This was collected on a (SCANNER AND ACQUISITON DETAILS HERE). The first row of FIG. 6 shows the uncorrected reconstructions, and the second row shows the b0 corrected reconstructions using CG-SENSE with 40 time segments. The columns of FIG. 6 show the NUFFT, iGROG and GROG reconstructions respectively.

Calculating A^{H}b using NUFFT took 24 s, while iGROG and GROG took about 1 s to calculate A^{H}_{grid}b. Calculating 100 CG iterations using the standard Toeplitz formulation took 16 s, while 100 CG iterations with iGROG/GROG took 5 s.

Calculating A^{H}b using NUFFT took 124 s, while iGROG and GROG took about 3 s to calculate A^{H}_{grid}b. Calculating 40 CG iterations using the standard Toeplitz formulation took 500 s, while 40 CG iterations with iGROG/GROG took 45 s.

1. A method for magnetic resonance imaging, the method comprising:
a) performing by an MRI scanner an MRI scan to acquire non-Cartesian k-space MRI acquisition data;
b) estimating by the MRI scanner Cartesian k-space data from the non-Cartesian k-space MRI acquisition data, wherein the estimating comprises estimating each Cartesian k-space coordinate in the Cartesian k-space data from multiple neighboring non-Cartesian k-space coordinates using an ensemble of GRAPPA kernels, where each of the GRAPPA kernels is obtained from a non-linear model trained on calibration data from an MRI calibration scan;
c) reconstructing by the MRI scanner an MRI image from the estimated Cartesian k-space data.

2. The method of claim 1 wherein the non-linear model is a neural network.

3. The method of claim 1 wherein the non-linear model is a kernel regression model.

4. The method of claim 1 wherein the non-linear model is a linear model with heuristically chosen non-linear features lifting.

5. The method of claim 4 wherein the non-linear features lifting comprises sine and cosine positional encoding.
